(19) United States
(12) Patent Application Publication
(10) Pub. No.: US 2004/0077178 A1
(43) Pub. Date: Apr. 22, 2004

(54) Method for laterally etching a semiconductor structure

(75) Inventors: Chan-Syun Yang, San Jose, CA (US); Anisul H. Khan, Santa Clara, CA (US); Ajay Kumar, Sunnyvale, CA (US); Padmapani C. Nallan, San Jose, CA (US)

Correspondence Address: APPLIED MATERIALS, INC., Patent Department, P.O. Box 450A, Santa Clara, CA, 95052, US

(73) Assignee: Applied Materials, Inc.

(21) Appl. No.: 10/273,802

(22) Filed: Oct. 17, 2002

(51) Int. Cl. H01L 21/302; H01L 21/461

(52) U.S. Cl. 438/710

(57) ABSTRACT

A method for laterally etching a structure on a semiconductor substrate comprising depositing a protective mask that thins towards a bottom of the structure and lateral etching a wall of the structure to form a notch or to release the structure.

### BACKGROUND OF THE INVENTION

1. Field of the Invention

The present invention generally relates to semiconductor substrate processing systems. More specifically, the present invention relates to a method for performing an etch process in a semiconductor substrate processing system.

2. Description of the Related Art

Micro Electro-Mechanic Systems (MEMS) are very small electro-mechanical devices such as actuators, sensors, and the like. MEMS combine many of the most desirable aspects of conventional mechanical and electronic solid-state devices. Unlike conventional mechanical devices, MEMS are generally fabricated on a semiconductor substrate such as a silicon (Si) wafer and may be monolithically integrated with electronic circuits that are formed on the same substrate.

During manufacturing of MEMS, every effort is made to use the processes and semiconductor substrate processing systems that have been developed for fabrication of electronic integrated circuits. However, manufacturing of the MEMS comprises processes that have no analogy during fabrication of the electronic integrated circuits. One such process is releasing a MEMS structure from a semiconductor substrate when the structure has been formed. The structure generally is an object like a vertical linear or circular wall, column, and the like that has a width of about 1 to 20 μm and an aspect ratio of about 5 to 50 or more. The term aspect ratio as used herein refers to a height of the structure divided by its smallest width as measured in the plan view.

The MEMS structures are generally formed using a deep trench etch process. Once the structure is formed, to release the MEMS structure, the substrate is etched using a buffered oxide etch (BOE) process that comprises a wet dip of the substrate in a solution of hydrogen fluoride (HF). However, a delicate MEMS structure, as it thins during the BOE process, may be broken by forces of surface tension during the wet dip resulting in permanent damage to the structure or substrate.

Therefore, there is a need in the art for a method of releasing a MEMS structure from a substrate that does not use a wet dip etching technique.

### SUMMARY OF THE INVENTION

The present invention is a method of lateral plasma etching a semiconductor structure including a technique for releasing of a MEMS structure. The method also finds use in laterally notching semiconductor structures such as gate structures. The method comprises depositing a protective mask having a thickness that decreases towards a bottom of the structure and performing a lateral plasma etch process that laterally etches a wall at the bottom of the structure until the structure is notched to a predetermined width or released. In one embodiment, the protective mask is a polymeric coating that is formed using a plasma comprising at least one of a fluorocarbon gas or a hydrofluorocarbon gas such as C₄F₈, CHF₃, and the like.

### BRIEF DESCRIPTION OF THE DRAWINGS

The teachings of the present invention can be readily understood by considering the following detailed description in conjunction with the accompanying drawings, in which:

FIGS. 1A-1D depict a sequence of schematic, cross-sectional views of a substrate having MEMS structures being released in accordance with an example of an application for the present invention;

FIGS. 2A-2D depict a sequence of schematic, cross-sectional views of a substrate having a gate structure of a field effect transistor being notched in accordance with an example of an application for the present invention;

FIG. 3 is a flow diagram of one embodiment of the inventive method; and

FIG. 4 is a schematic diagram of a plasma processing apparatus of the kind used in performing the etch process according to one embodiment of the present invention.

To facilitate understanding, identical reference numerals have been used, where possible, to designate identical elements that are common to the figures.

It is to be noted, however, that the appended drawings illustrate only typical embodiments of this invention and are therefore not to be considered limiting of its scope, for the invention may admit to other equally effective embodiments.

### DETAILED DESCRIPTION

The present invention is a method of lateral plasma etching a semiconductor structure that may be used for notching or releasing a semiconductor structure. The method comprises a deposition process and a lateral etch process. The deposition process is a plasma process that forms a protective mask upon a structure using at least one of a fluorocarbon gas or a hydrofluorocarbon gas such as at least one of C₄F₈, CHF₃, and the like. When the protective mask has been formed, the lateral etch process etches the structure near the bottom of the structure. The lateral etch process has a duration that continues until the structure such as a MEMS structure, a gate structure of a field effect transistor (FET), and the like is notched to a predetermined width or the structure such a MEMS structure and the like is released from the semiconductor substrate (also referred herein as a wafer).

The lateral etch process is a plasma process that uses an etchant gas such as sulfur hexafluoride (SF₆) and the like. In accordance with the inventive method, the structure such as a MEMS structure may be formed and notched or released using a sequence of the processes that are performed in a single etch reactor. In one embodiment, the inventive method facilitates in-situ notching or release of the structure that has been formed on the wafer using an etch process such as a Time Multiplex Gas Modulation (TMGM) process.

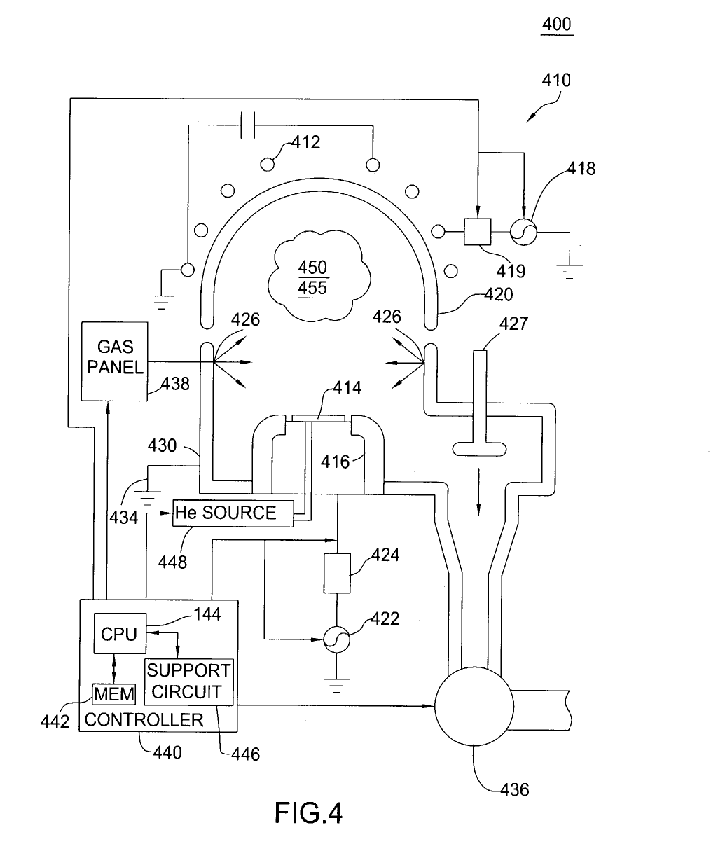

As described in detail with respect to FIG. 4 below, the method can be reduced to practice, for example, in a Decoupled Plasma Source—Deep Trench (DPS-DT) reactor of the CENTURA® semiconductor wafer processing systems available from Applied Materials, Inc. of Santa Clara, Calif. In one embodiment, the DPS-DT reactor uses a 12.56 MHz inductive plasma source to produce a high density plasma and a wafer is biased by a 400 kHz source of bias power that provides a pulsed or continuous output. The DPS-DT reactor allows independent control of ion energy and plasma density, has a wide process window over changes in the plasma source and bias power, pressure, and gas chemistry, and may use an endpoint detection system to determine an end of the etch process.

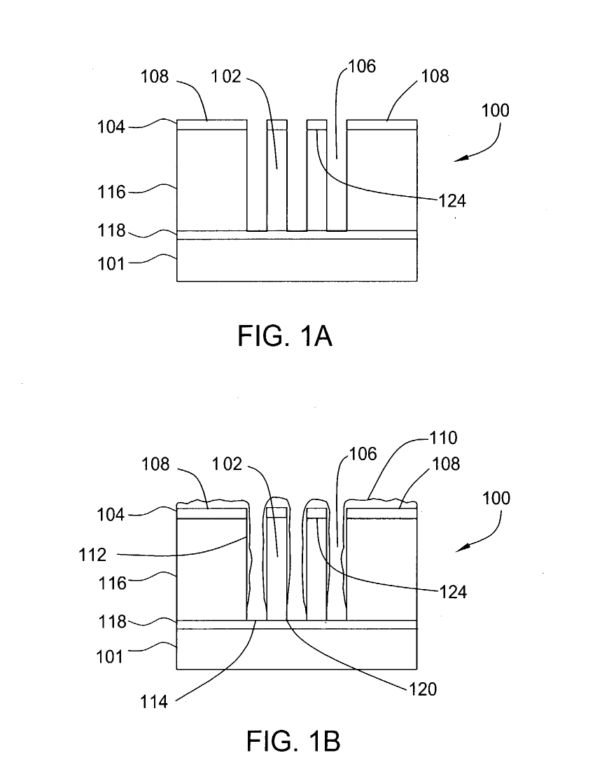

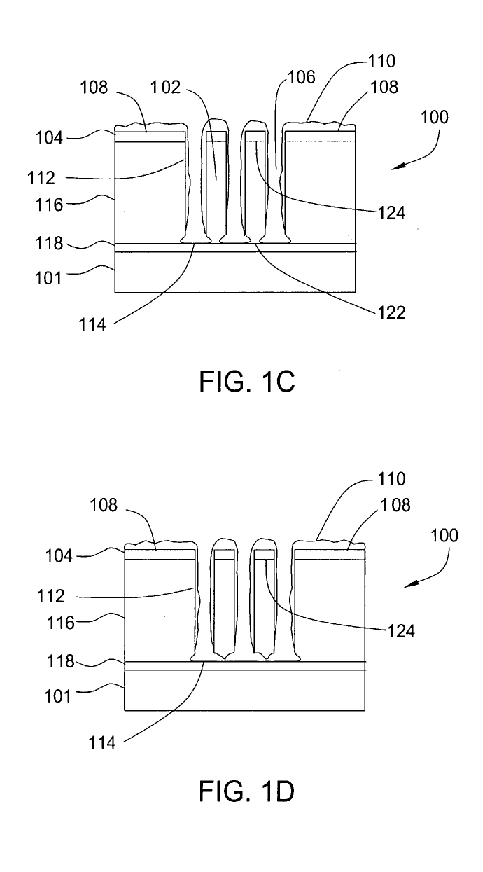

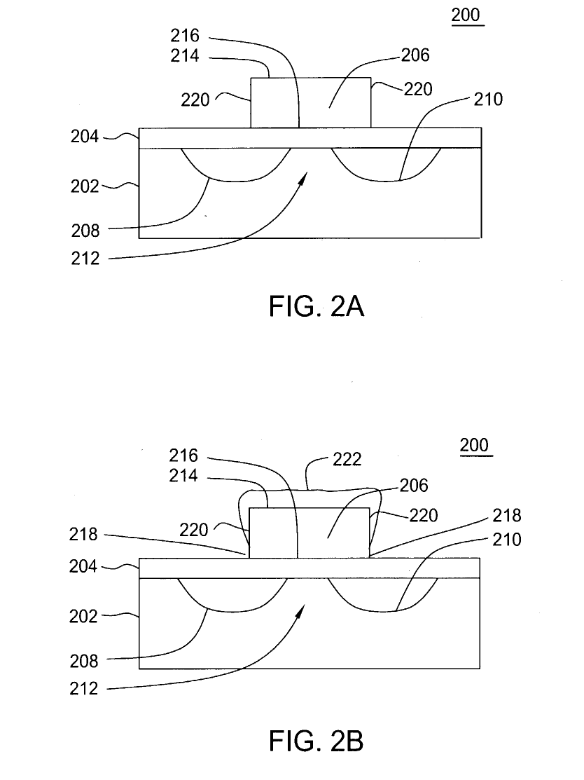

FIGS. 1A-1D depict a sequence of schematic, cross-sectional views of a substrate having MEMS structures that are being notched and released in accordance with an example of an application for the present invention. The cross-sectional views in FIGS. 1A-1D relate to individual processes that are used to release the structures. The images in FIGS. 1A-1D are not depicted to scale and are simplified for illustrative purposes.

FIG. 1A depicts one illustrative example of a film stack 100 having an etch stop layer 118, a layer 116 that comprises a plurality of the MEMS structures 102, and an etch mask layer 104 deposited upon a semiconductor substrate 101 (e.g., silicon (Si) substrate). The layer 116 generally is formed from silicon, polysilicon, and the like to a thickness of about 1 to 20 μm. The etch stop layer 118 is generally formed from silicon dioxide (SiO₂), silicon carbide (SiC), silicon nitride (Si₃N₄), and the like. In an alternative embodiment (not shown), the structures 102 may be formed in the layer 116 that is deposited directly on the substrate 101, i.e., when there is no etch stop layer between the layer 116 and the substrate 101. The material of the layer 118 is selected to best define an end point during the etch process that is used to form the structure 102, and to provide best protection to the substrate 101 during the lateral etch process (discussed in reference to FIG. 1C below).

The structures 102 (e.g., walls, columns, and the like) are generally formed using a plasma etch process, e.g., a TMGM process that comprises a serial sequence of alternating etch and deposition steps. One such TMGM process is disclosed in U.S. patent application Ser. No. ______, filed simultaneously herewith (Attorney docket number 6241), which is incorporated herein by reference. The process etches the structure for a period of time then deposits a protective film upon the previously etched surface to protect the surface, typically the sidewalls of the trench, from further etching. During the etch step, the substrate bias power is pulsed. These two steps are repeated as a deeper and deeper trench is formed. The deposition step uses a fluorocarbon or hydrofluorocarbon plasma to create the film of protective polymeric passivation layer upon the etch mask and sidewalls of the trench. The etch step isotropically etches a bottom of the trench.

The trench 106 generally has a width of about 1 to 20 μm and an aspect ratio of about 5 to 50 or more. Herein the term aspect ratio refers to a height of the trench divided by its width. The etch mask 104 protects the structures 102 from overetching during the lateral etch process i.e., the mask 106 protects the top of the structures 102 from eroding. In one embodiment, the etch mask 104 is used to form the structures 102 and the mask material that remains on the structures 102 after the structures have been formed is used as the mask 104. Such remaining etch mask can be either a photoresist mask or a hard mask formed from an inorganic material such as SiO₂, SiC, amorphous carbon, and the like. In an alternative embodiment (not shown), the etch mask that is used during the TMGM process that forms the structure 102 may be stripped upon completion of the process using, e.g., a conventional dry or wet stripping technique, thus leaving the structures 102 with no mask. In a further alternative, the mask may be replaced with a new photoresist or hard mask prior to the lateral etch process being used.

FIG. 1B depicts the structures 102 after application of the protective mask 110. In one embodiment, the protective mask 110 is a polymeric coating that is formed during a plasma deposition process that uses a passivating gas comprising at least one of C₄F₈, CHF₃, and the like. The process may be performed either in a dedicated reactor or in the same reactor that is used to form the trenches 102, e.g., a DPS-DT reactor. In the illustrative embodiment, the DPS-DT reactor is used to form the structures 102 and to deposit in situ the protective mask 110.

During the plasma deposition process, the protective mask 110 forms upon the etch mask 104 and sidewalls 112 of the structure 102. In the alternative embodiment, when the mask 104 is stripped prior to the deposition process as discussed above, the protective mask 110 forms upon the layer 116 and upon the top surfaces 124 and the sidewalls 112 of the structures 102. A thickness of the protective mask 110, as applied, naturally decreases towards a bottom 114 of the trench 106 and is minimal in a corners 120 that are formed by the etch stop layer 118 and the sidewalls 112 of the trench. As such, the mask 110 protects the upper portion of the sidewall 112 but leaves an area near the corner 120 exposed to the etchant plasma during the lateral etch process (discussed in reference to FIG. 1C below). The deposition process may be adjusted to produce a protective mask that has the desired profile and thickness, e.g., by controlling the process parameters such as plasma density, wafer bias power, gas pressure, process time, and the like.

The protective mask 110 is being gradually consumed during the lateral etch process (discussed in reference to FIG. 1C below) that is used to notch or release the structures 102. As such, the mask should be formed to a thickness that is sufficient to protect the structure 102 during the time period that is necessary for the lateral etch process to be completed. In general, a high aspect ratio structure may require a mask 110 that has a greater thickness than the mask for a low aspect ratio structure having the same width in the plan view.

In an exemplary embodiment, when the DPS-DT reactor is used to form the mask 110, the deposition process supplies about 20 to 500 sccm of C₄F₈, applies power to an antenna of about 200 to 3000 Watts, applies a bias power of about 0 to 100 Watts, and maintains a pressure in the reactor of about 10 to 100 mTorr. One specific process recipe provides 300 sccm of C₄F₈, applies 1800 Watts to the antenna, applies no bias power, and maintains a pressure in the reactor at 40 mTorr. A temperature of the wafer 101 during the deposition process is maintained at about 10 to 100 degrees Celsius. A duration of the deposition process is generally about 5 to 20 seconds.

FIG. 1C depicts the structures 102 that are notched at bottoms 122 using the lateral etch process that etches the sidewalls 112 of the structure 102 near the corners 120. As discussed above in reference to FIG. 1B, the sidewalls 112 are not protected by the mask 110 in the areas near the corners 120, or the mask 110 is so thin in such areas that the etchant plasma promptly removes the mask 110 and laterally etches the sidewalls 112. In FIG. 1C, the lateral etch process is terminated when the sidewalls 112 have been notched to a predetermined width by controlling, e.g., a duration of the lateral etch process.

FIG. 1D depicts the structures 102 that have been released from the wafer 100 using the lateral etch process that continues until each structure 102 is totally released from the wafer 100.

The lateral etch process of the present invention is a plasma process that uses an etchant gas such as sulfur hexafluoride (SF₆) and the like. The process may be performed either in a dedicated etch reactor or in the same reactor that is used to form the trenches 102 or the protective mask 110. In one embodiment, all these processes are sequentially accomplished in situ in the same etch reactor, e.g., a DPS-DT reactor.

In an exemplary embodiment, when the DPS-DT reactor is used to notch or release the structures 102, the lateral etch process supplies about 20 to 500 sccm of SF₆, applies power to an antenna of about 200 to 3000 Watts, applies a bias power of about 0 to 300 Watts, and maintains a pressure in the reactor of about 5 to 500 mTorr and a wafer temperature at about 10 to 100 degrees Celsius. One specific process recipe provides 250 sccm of SF₆, applies 1000 Watts to the antenna, applies 20 Watts of the bias power, and maintains a pressure in the reactor at 20 mTorr and a wafer temperature at 10 degrees Celsius. Such lateral etch process provides a relative selectivity to the silicon of the structure 102 over the polymeric coating of the mask 110 of about 20 or greater and as such facilitates releasing of the MEMS structures that have a width of about 1 to 20 μm and an aspect ratio of about 5 to 50 or more.

Depending upon the application of the structure, any remaining mask material may or may not be removed. If removal is desired, a conventional polymer removal solution, such as a mixture of sulfuric acid and hydrogen peroxide, can be used.

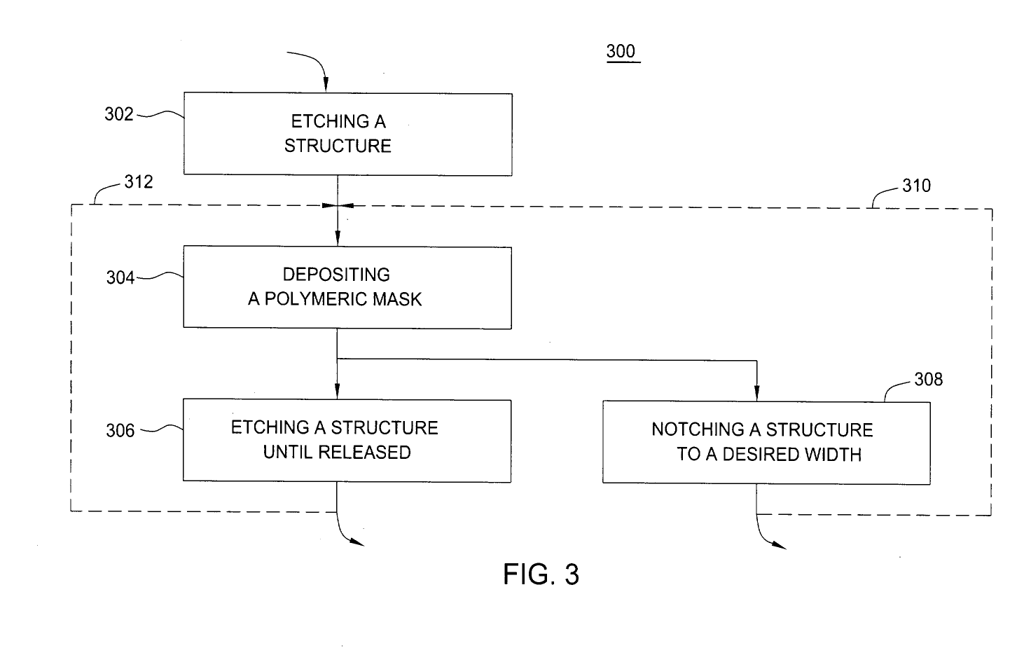

FIG. 3 is a flow diagram of an example of a method 300 for notching or releasing the structures 102 in accordance with one embodiment of the invention. For best understanding, the reader should refer simultaneously to FIG. 1 and FIG. 3.

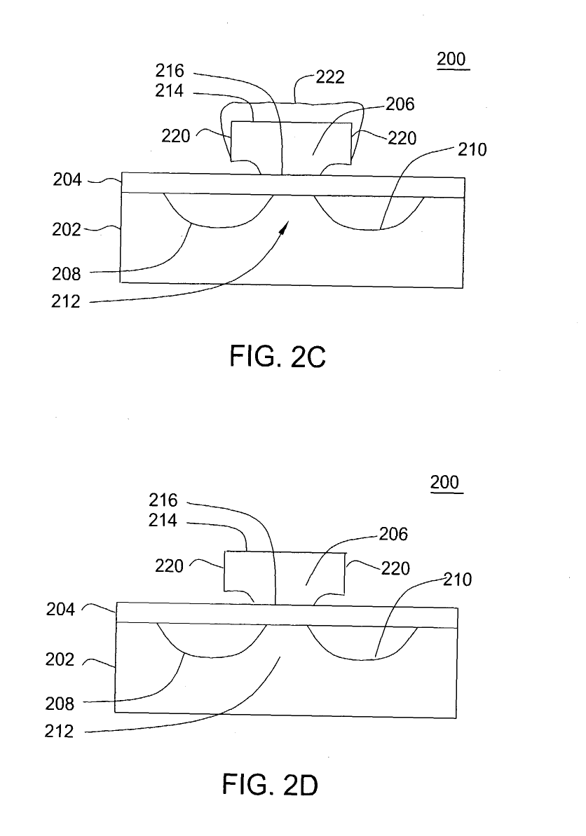

The method 300 begins, at step 302, by forming the structures 102 on the wafer 100 using, e.g., a TMGM process or another deep trench etching process. At step 304, the protective mask 110 is formed upon the structures 102 using a plasma deposition process. In one embodiment of the invention, the mask deposition step of the TMGM process remains active for an extended period, e.g., 15 seconds, to form the mask for lateral etching. At step 306, the structures 102 are etched at the bottoms 122 using the lateral etch process until each structure is totally released from the wafer 100. Alternatively, at step 308, the structure 102 or a feature such as a gate electrode of a field effect transistor and the like (discussed in reference to FIG. 2 below) may be notched using the lateral etch process to a predetermined width, e.g., by controlling a duration of the lateral etch process.

At step 306 (or step 308), the lateral etch process gradually consumes the protective mask 110 making it thinner as the process progresses. In an alternative embodiment, when the protective mask 110 is substantially removed from the sidewalls 112 before the structure 102 has been either released or notched to a predetermined width, step 306 (or step 308) may be temporarily terminated and then step 304 repeated to reapply the protective mask 110. Reapplication of the mask is indicated by dashed lines 310 and 312. After the mask 110 has been reapplied, step 304 is terminated and step 306 (or step 308) commences. In general, the method 300 may comprise one or more cycles each comprising step 304 and step 306 (or step 308). In one embodiment, when the layer 116 is formed directly on the wafer 100, such cycles may be used to reduce the wafer 100 undercut by depositing a protective polymer into the regions, e.g., at the bottom 114, that became exposed to the etchant plasma during the preceding step 306 (or step 308).

FIGS. 2A-2D depict a sequence of schematic, cross-sectional views of a substrate having a gate structure of field effect transistor, e.g., a complementary metal-oxide-semiconductor (CMOS) transistor, wherein the gate electrode is being notched in accordance with an example of an application for the present invention. Similar to FIG. 1, the cross-sectional views in FIGS. 2A-2D relate to individual processes that are used to notch the gate structure and the images are not depicted to scale and are simplified for illustrative purposes.

FIG. 2A depicts one illustrative example of a gate structure 200 of the CMOS transistor. The gate structure 200 is formed in a wafer 202 (e.g., a silicon wafer) and comprises heavily doped (e.g., by boron (B) or arsenic (As)) wells 208 and 210 that are separated by a channel 212, a thin dielectric layer 204 (e.g., a silicon dioxide (SiO₂) layer), and an electrode 206 having an upper surface 214 and a bottom surface 216. The electrode 206 is generally formed from polysilicon (Si) to a thickness of about 100 to 200 nm. The polysilicon layer is patterned to position the electrode 206 over the channel 212 and portions of the wells 208 and 210. Operational speed of the gate structure 200 increases when the width of the channel 212 is decreased. Decreasing the width of the channel 212 requires a commensurate decrease in the width of the bottom surface 216 of the electrode 206. The upper surface 214 of the electrode 206 should be large enough to allow for metallization and connectivity of the electrode 206 to the wiring layers of the integrated circuitry formed on the wafer 202, however, the width of the bottom surface 216 may be decreased by notching the electrode 206 using the lateral etch process of the present invention. Consequently, the gate structure 200 with a narrower channel 212 and greater operational speed may be fabricated as a result of the present invention.

FIG. 2B depicts the gate structure 200 after application of the protective mask 222 upon the electrode 206 using a plasma deposition process of step 304 as described above in reference to FIG. 1B. Similar to the protective mask 110, the mask 222 thins towards the dielectric layer 204 and has a minimal width in a corner 218 that is formed by the layer 204 and the sidewall 220 of the electrode 206. As such, the mask 222 protects the upper portion of the sidewalls 220 and the upper surface 214 of the electrode 206 and leaves an area near the corner 218 exposed to the etchant plasma during the lateral etch process.

FIG. 2C depicts the gate structure 200 after the electrode 206 has been notched using the lateral etch process of step 308 of FIG. 3 (above described). During step 308, the lateral etch process uses the process recipe that is described in reference to FIG. 1C and step 306, however, the process time during step 308 is terminated when the electrode 206 is notched to a predetermined width.

Finally, FIG. 2D depicts the gate structure 200 after the protective mask 222 has been optionally removed using, e.g., a conventional polymer stripping process, either in situ or in a dedicated dry or wet wafer processing reactor. Depending upon the application of the structure, any remaining mask material may or may not be removed. If removal is desired, a conventional polymer removal solution, such as a mixture of sulfuric acid and hydrogen peroxide, can be used.

FIG. 4 depicts a schematic diagram of the DPS-DT reactor that may be used to accomplish the method of the present invention. A reactor 400 comprises a process chamber 410 having at least one inductive coil antenna segment 412, positioned exterior to a dielectric, dome-shaped ceiling 420 (referred to herein as the dome 420). Other chambers may have other types of ceilings, e.g., a flat ceiling. The antenna segment 412 is coupled to a radio-frequency (RF) plasma source 418 that is generally capable of producing an RF signal having a tunable frequency of about 50 kHz and 13.56 MHz and has a power of 200 to 3000 Watts. The RF source 418 is coupled to the antenna 412 through a matching network 419. Process chamber 410 also includes a wafer support pedestal (cathode) 416 that is coupled to a biasing source 422 that is generally capable of producing an RF signal having a tunable frequency between 50 kHz and 13.56 MHz and a power between 0 and 500 Watts. The source 422 is coupled to the cathode 416 through a matching network 424. Optionally, the source 422 may be a DC or pulsed DC source. The chamber 410 also contains a conductive chamber wall 430 that is connected to an electrical ground 434. A controller 440 comprising a central processing unit (CPU) 444, a memory 442, and support circuits 446 for the CPU 444 is coupled to the various components of the DPS-DT etch process chamber 410 to facilitate control of the etch process.

In operation, a wafer 414 is placed on the wafer support pedestal 416 and gaseous components are supplied from a gas panel 438 to the process chamber 410 through entry ports 426 to form a gaseous mixture 450. The gaseous mixture 450 is ignited into a plasma 455 in the process chamber 410 by applying RF power from the RF sources 418 and 422 respectively to the antenna 412 and the cathode 416. The pressure within the interior of the etch chamber 410 is controlled using the gas panel 438 and a throttle valve 427 situated between the chamber 410 and a vacuum pump 436. The temperature at the inner surface of the chamber walls 430 is controlled using liquid-containing conduits (not shown) that are located in the walls 430 of the chamber 410.

The temperature of the wafer 414 is controlled by stabilizing the temperature of the support pedestal 416 and flowing helium gas from source 448 to channels formed by the back of the wafer 414 and grooves (not shown) on the pedestal surface. The helium gas is used to facilitate heat transfer between the pedestal 416 and the wafer 414. During the processing, the wafer 414 is heated by a resistive heater within the pedestal to a steady state temperature and the helium facilitates uniform heating of the wafer 414. Using thermal control of both the dome 420 and the pedestal 416, the wafer 414 is maintained at a temperature of between 10 and 500 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the chamber as described above, the CPU 444 may be one of any form of general purpose computer processor that can be used in an industrial setting for controlling various chambers and sub-processors. The memory 442 is coupled to the CPU 444. The memory 442, or computer-readable medium, may be one or more of readily available memory such as random access memory (RAM), read only memory (ROM), floppy disk, hard disk, or any other form of digital storage, local or remote. The support circuits 446 are coupled to the CPU 444 for supporting the processor in a conventional manner. These circuits include cache, power supplies, clock circuits, input/output circuitry and subsystems, and the like. Software routines that, when executed by the CPU 444, cause the reactor to perform processes of the present invention are generally stored in the memory 442. The software routines may also be stored and/or executed by a second CPU (not shown) that is remotely located from the hardware being controlled by the CPU 444.

The software routines are executed after the wafer 414 is positioned on the pedestal 416. The software routines, when executed by the CPU 444, transform the general purpose computer into a specific purpose computer (controller) 440 that controls the chamber operation such that the lateral etch process is performed in accordance with the method of the present invention.

Although the present invention is discussed as being implemented as a software routine, some of the method steps that are disclosed therein may be performed in hardware as well as by the software controller. As such, the invention may be implemented in software as executed upon a computer system, in hardware as an application specific integrated circuit or other type of hardware implementation, or a combination of software and hardware.

The forgoing discussion referred to notching or releasing a MEMS structure and notching a gate electrode of a FET transistor, however, fabrication of other structures and features used in the MEMS or integrated electronic circuits can benefit from the invention.

The invention can be practiced in other semiconductor processing systems wherein the processing parameters may be adjusted to achieve acceptable characteristics by those skilled in the art by utilizing the teachings disclosed herein without departing from the spirit of the invention.

While foregoing is directed to the illustrative embodiment of the present invention, other and further embodiments of the invention may be devised without departing from the basic scope thereof, and the scope thereof is determined by the claims that follow.

What claimed is:

1. A method for laterally etching a structure on a semiconductor substrate, comprising:
(a) supplying the substrate having the structure;
(b) depositing upon the structure a protective etch mask having a thickness that decreases towards a bottom of the structure; and
(c) laterally etching the bottom of the structure to form a notch at the bottom of the structure to a predetermined width or release the structure from the substrate.

2. The method of claim 1 wherein the substrate comprises a plurality of the structures.

3. The method of claim 1 wherein the structure is a portion of a Micro Electro-Mechanic Systems (MEMS) structure.

4. The method of claim 1 wherein the structure has a width between 1 to 20 μm and an aspect ratio of about 5 to 50.

5. The method of claim 1 wherein step (b) uses a plasma comprising at least one of a fluorocarbon gas or a hydrofluorocarbon gas.

6. The method of claim 5 wherein the fluorocarbon gas comprises C₄F₈.

7. The method of claim 5 wherein the hydrofluorocarbon gas comprises CHF₃.

8. The method of claim 6 further comprising:
supplying about 20 to 500 sccm of C₄F₈ and maintaining a pressure in a process chamber at about 10 to 100 mTorr;
applying a bias power to a cathode electrode of about 0 to 300 W and applying power to an inductively coupled antenna of about 200 to 3000 W; and
maintaining the substrate at a temperature of about 10 to 100 degrees Celsius.

9. The method of claim 1 wherein step (a), step (b), and step (c) are performed sequentially in the same reactor.

10. The method of claim 1 comprising at least one cycle comprising step (b) and step (c).

11. The method of claim 1 wherein the lateral etching step uses a plasma comprising SF₆.

12. The method of claim 11 further comprising:
supplying about 20 to 500 sccm of SF₆ and maintaining a pressure in a process chamber at about 5 to 500 mTorr;
applying a substrate bias power of about 0 to 300 W and applying power to an inductively coupled antenna of about 200 to 3000 W; and
maintaining the substrate at a temperature of about 10 to 100 degrees Celsius.

13. A method of fabricating a gate structure on a semiconductor substrate, comprising:
(a) supplying a substrate comprising a patterned gate electrode;
(b) depositing, upon the patterned gate electrode, a protective etch mask having a thickness that decreases towards a bottom of the gate electrode; and
(c) laterally etching the bottom of the patterned gate electrode to form a notch at the bottom of the patterned gate electrode.

14. The method of claim 13 wherein the gate structure is a gate structure of a field effect transistor.

15. The method of claim 13 wherein step (b) uses a plasma comprising at least one of a fluorocarbon gas or a hydrofluorocarbon gas.

16. The method of claim 15 wherein the fluorocarbon gas comprises C₄F₈.

17. The method of claim 15 wherein the hydrofluorocarbon gas comprises CHF₃.

18. The method of claim 16 further comprising:
supplying about 20 to 500 sccm of C₄F₈ and maintaining a pressure in a process chamber at about 10 to 100 mTorr;
applying a bias power to a cathode electrode of about 0 to 300 W and applying power to an inductively coupled antenna of about 200 to 3000 W; and
maintaining the substrate at a temperature of about 10 to 100 degrees Celsius.

19. The method of claim 13 wherein step (a), step (b), and step (c) are performed sequentially in the same reactor.

20. The method of claim 13 comprising at least one cycle comprising step (b) and step (c).

21. The method of claim 13 wherein step (c) uses a plasma comprising SF₆.

22. The method of claim 21 further comprising:
supplying about 20 to 500 sccm of SF₆ and maintaining a pressure in a process chamber at about 5 to 500 mTorr;
applying a substrate bias power of about 0 to 300 W and applying power to an inductively coupled antenna of about 200 to 3000 W; and
maintaining the substrate at a temperature of about 10 to 100 degrees Celsius.

23. A computer-readable medium containing software that when executed by a computer causes an etch reactor to perform a process of laterally etching a structure on a semiconductor substrate, comprising:
(a) supplying the substrate having the structure;
(b) depositing upon the structure a protective etch mask having a thickness that decreases towards a bottom of the structure; and
(c) laterally etching the bottom of the structure to form a notch at the bottom of the structure to a predetermined width or release the structure from the substrate.

24. The computer-readable medium of claim 23 wherein the substrate comprises a plurality of the structures.

25. The computer-readable medium of claim 23 wherein the structure is a portion of a Micro Electro-Mechanic Systems (MEMS) structure.

26. The computer-readable medium of claim 23 wherein the structure has a width between 1 to 20 μm and an aspect ratio of about 5 to 50.

27. The computer-readable medium of claim 23 wherein step (b) uses a plasma comprising at least one of a fluorocarbon gas or a hydrofluorocarbon gas.

28. The computer-readable medium of claim 27 wherein the fluorocarbon gas comprises C₄F₈.

29. The computer-readable medium of claim 27 wherein the hydrofluorocarbon gas comprises CHF₃.

30. The computer-readable medium of claim 28 further comprising:
supplying about 20 to 500 sccm of C₄F₈ and maintaining a pressure in a process chamber at about 10 to 100 mTorr;
applying a bias power to a cathode electrode of about 0 to 300 W and applying power to an inductively coupled antenna of about 200 to 3000 W; and
maintaining the substrate at a temperature of about 10 to 100 degrees Celsius.

31. The computer-readable medium of claim 23 wherein step (a), step (b), and step (c) are performed sequentially in the same reactor.

32. The computer-readable medium of claim 23 comprising at least one cycle comprising of step (b) and step (c).

33. The computer-readable medium of claim 23 wherein the lateral etching step uses a plasma comprising SF₆.

34. The computer-readable medium of claim 33 further comprising:
supplying about 20 to 500 sccm of SF₆ and maintaining a pressure in a process chamber at about 5 to 500 mTorr;
applying a substrate bias power of about 0 to 300 W and applying power to an inductively coupled antenna of about 200 to 3000 W; and
maintaining the substrate at a temperature of about 10 to 100 degrees Celsius.
